(19) United States
(12) Patent Application Publication
(10) Pub. No.: US 2006/0160249 A1
(43) Pub. Date: Jul. 20, 2006

(54) METHOD FOR FABRICATING BIOCHIPS OR BIOSENSORS USING CD/DVD MAKING COMPATIBLE PROCESSES

(76) Inventors: Tien-Yu Chou, Tao-Yuan Hsien (TW); Jyh-Huei Lay, Tao-Yuan Hsien (TW); Irene Chen, Tao-Yuan Hsien (TW); Jo-Wen Wu, Tao-Yuan Hsien (TW); Yen-Heng Lin, Tao-Yuan Hsien (TW); Chung-Lang Liao, Tao-Yuan Hsien (TW); Kuo-Hsiung Yen, Tao-Yuan Hsien (TW); Shi-Hui Zhang, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 10/905,679

(22) Filed: Jan. 17, 2005

(51) Int. Cl. H01L 21/00

(52) U.S. Cl. 438/1

(57) ABSTRACT

A method of manufacturing a plastic biochip or a biosensor test strip, which is compatible with standard CD/DVD making processes. The method includes substrate injection press molding, followed by seamless magnetic biosensor sputtering. If necessary, the sputtered biosensor is cut off from the substrate.

### BACKGROUND OF THE INVENTION

1. Field of the Invention

The present invention relates to a method for manufacturing a plastic biochip or a biosensor test strip, and more specifically, to a method applied with a seamless sputtering compatible to a standard optical disk manufacturing process.

2. Description of the Prior Art

There is an enormous need to make clinical assays faster, cheaper, and simpler to perform. One way towards this goal has been through miniaturization and integration of various assay operations. Currently, a number of biochip assays are commercially available or under development.

Two kinds of biochip technology are applied in the diagnosis and analysis market: an optical analysis biochip and an electrochemical biochip or biosensor. The optical analysis biochip applies a luminescent detection method for quantitative affinity sensing and for selective quantitative determination of luminescent constituents of optically opaque solutions. The electrochemical biochip or biosensor applied with metal microelectrodes and micro-channels detects current signals generated by reactions of test samples and chemical or biological agents for determining results. The microelectrical engineering techniques applied for generation of micro-channels are in their preliminary development stages without any possibility for mass production. Additionally, electrochemical sensors are generated on a glass carrier, which is fragile and expensive.

### SUMMARY OF THE INVENTION

It is therefore a primary objective of the claimed invention to provide a method for manufacturing a plastic biochip or a biosensor test strip applied with insert mold generation, injection press molding, seamless sputtering, and ultra wave melting and fixing, for mass production to overcome the problems of the prior art.

According to a first preferred embodiment of the claimed invention, the claimed invention provides a method compatible with a standard optical disk manufacturing process for fabricating electrochemical test strips. The method comprises injection press molding for generating polymer substrates, and seamless sputtering for generating micro-sensing electrodes onto the polymer substrates. The seamless sputtering further comprises applying a metal mask having an electrode pattern to a first surface of the polymer substrate, and a magnetic material to a second surface of the polymer substrate. A stamper having a die with a 33 mm diameter central hole is provided in the injection press molding for generating a chip whose thickness and specification is the same to a regular optical disk, being between 0.6 mm and 2.0 mm. After the seamless sputtering, the method comprises a cut off process.

According to another preferred embodiment according to the claimed invention, the claimed invention provides a method compatible with a standard optical disk manufacturing process for generating a biochip. The method comprises providing an insert mold having a pattern thereon wherein the pattern can be a channel, a depression, or a hole; injection press molding a polymer chip having the pattern of the insert mold; and seamless sputtering metal onto the polymer chip disposing micro-sensing electrodes. The seamless sputtering comprises applying a metal mask having an electrode pattern to a first surface of the polymer chip and a magnetic material to a second surface of the polymer chip. The chip having a pattern that is the same as the insert mold is a flat rectangular plate having a length and a width between 1 cm and 10 cm. The method further comprises ultra wave melting and fixing after the seamless sputtering.

These and other objectives of the claimed invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 is a flowchart of a first preferred embodiment according to the present invention.

FIG. 2 is a sectional diagram of the seamless sputtering process according to the present invention.

FIG. 3 is a top view of an optical disk having metal electrodes according to the present invention.

FIG. 4 is a flowchart of a second preferred embodiment according to the present invention.

### DETAILED DESCRIPTION OF THE PREFERRED EMBODIMENT

Biochip technology combined with microelectrical engineering techniques enables scientists and researches to attain numerous goals such as identifying genetic variations associated with disease, analyzing biochemical or enzymatic reactions, and discovering new drug targets within a single experiment. The method provided in the present invention applies a standard optical disk manufacturing process through processes of generating an insert mold, injection press molding, seamless magnetic sputtering, and ultra wave melting and fixing to achieve mass production with advantages of high yield and low costs.

A conventional optical disk manufacturing process is as follows:

Premastering;

Mastering;

Replication;

Printing; and

Packing.

Premastering: According to a specification, transfer formats of content such as video signals, voice signals, and so on, to be written onto an optical disk through signal-processing.

Mastering: Use a laser light to etch recording signals onto a mold generated by electrical casting.

Injection: Copy the contents on the mold to the optical disk by injection press molding.

Sputtering: A sputtered metal reflective layer is used to reflect laser light and can comprise gold, silver, copper or aluminum.

An optical disk manufactured by the above-mentioned conventional optical disk manufacturing process comprises a plastic substrate, a reflective layer, a passivation layer, and a printing layer. The plastic substrate comprises optical polycarbonate ester; the reflection layer comprises aluminum-copper, silver, or gold metal layers; the passivation layer comprises hard acrylic resin resistant to being oxidized and damaged, and the printing layer comprises UV printing ink for printing patterns by silk screen printing or planography.

The present invention can also apply an injection process to generate polymer substrates having holes. A bonding technique can be used to tightly bind polymer substrates having different holes. Such bonded substrate is called a cartridge in the following discussion. The hole allows testing samples to flow via channels to a predetermined testing area where the testing samples react with agents provided in the testing area. Then the testing samples pass and contact electrodes for generating potential to be analyzed by a reader.

The present invention utilizes the devices and processes of the conventional optical disk manufacturing process for injection molding of polymer substrates having channels or any pattern. Then, on the injection molded polymer substrates, the sputtering process is used to generate metal wires and microelectrode sensors. A metal mask having patterns is applied to sputter metal field on the polymer substrates. As a width of a wire of a pattern on the metal mask can be in the order of μm, to precisely transfer the patterns on the metal mask onto specific area on the polymer substrate the metal mask must be fixed tightly with the polymer substrate. In the present invention, an object having magnetic force such as a magnet is provided behind the polymer substrate to attract the metal mask tightly for sputtering an electrode pattern on the polymer substrate. If necessary, patterns on the substrate having the shape of an optical disk can be cut off to become any necessary shape.

Above all, distinguishing features of the present invention at least include:

1. Using a metal mask to seamless sputter metal onto the polymer substrate for generating metal electrodes so as to improve reliability and yield.

2. Electrodes can be generated directly on the polymer substrate.

3. Electrodes can be generated directly on the optical disk.

4. A cartridge can be any shape such as rectangular, square, circle, and so on.

5. The sputtering mask can be fixed by magnetic force.

Below are disclosed two preferred embodiments according to the present invention.

1. Fabricating a single layer electrochemical test strip

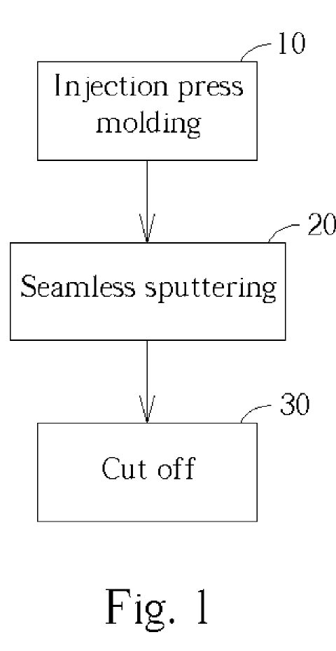

Please refer to FIG. 1. Illustrated in FIG. 1 is a flowchart according to a first preferred embodiment of the present invention. As shown in FIG. 1, at least 3 processes are necessary to fabricate a single layer electrochemical test strip:

(1) Step 10: Injecting press molding to generate a plant polymer substrate;

(2) Step 20: Seamless sputtering metal onto the polymer substrate to generate microelectrode sensors; and

(3) Step 30: Cut off.

The above-mentioned steps are described in more detail below.

Injecting press molding: Using a stamper having a die with a 33 mm diameter central hole and a CD/DVD injector to injection mold a polymer substrate having a thickness between 0.6 mm and 2.0 mm. As a single layer electrochemical test strip is fabricated, it is not necessary to generate any pattern on the injected substrate.

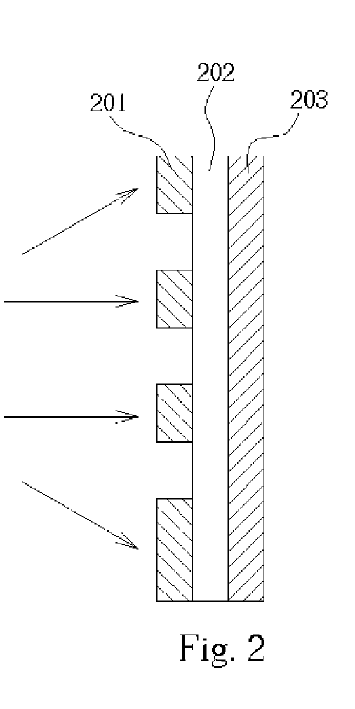

Seamless sputtering: Please refer to FIG. 2. Illustrated in FIG. 2 is a sectional diagram of the seamless sputtering process according to the present invention. As a width of a wire of a pattern on a metal mask 201 could be of the order of μm, to precisely transfer the patterns on the metal mask 201 onto specific area of a polymer substrate 202, the metal mask 201 must be fixed tightly with the polymer substrate 202. In the present invention, an object 203 having magnetic force such as a magnet or a permalloy is provided behind the polymer substrate 202 to attract the metal mask 201 tightly for sputtering an Au metal electrode pattern onto the polymer substrate 202.

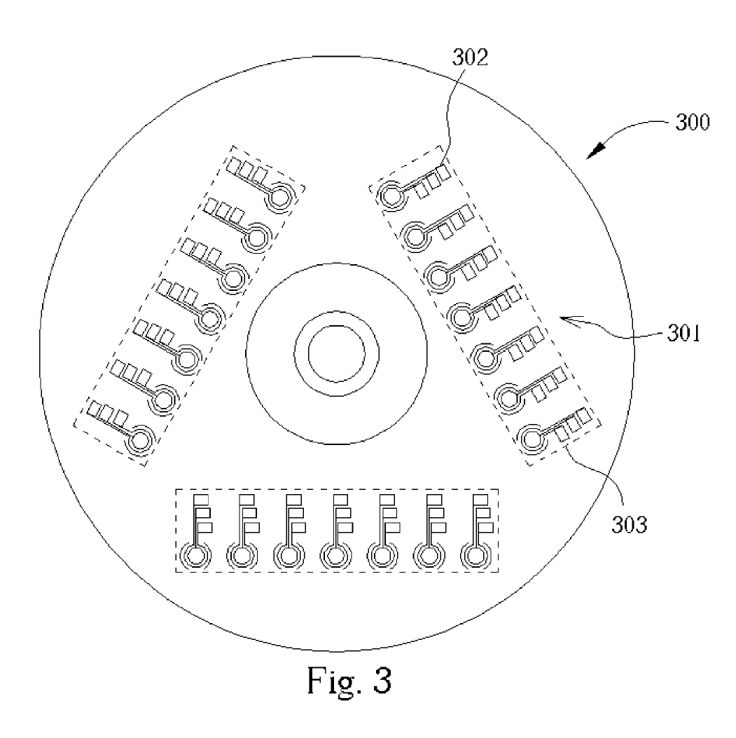

Cut off: Please refer to FIG. 3. Illustrated in FIG. 3 is an upper view of an optical disk having metal electrodes according to the present invention. As shown in FIG. 3, three biosensor strips 301 arranged on a transparent plastic optical disk 300 have to be separately cut off along a dotted line 303 in order to be used. Each strip 301 comprises a plurality of metal electrodes 302 sputtered thereon.

2. Fabricating a multi-layer biochip

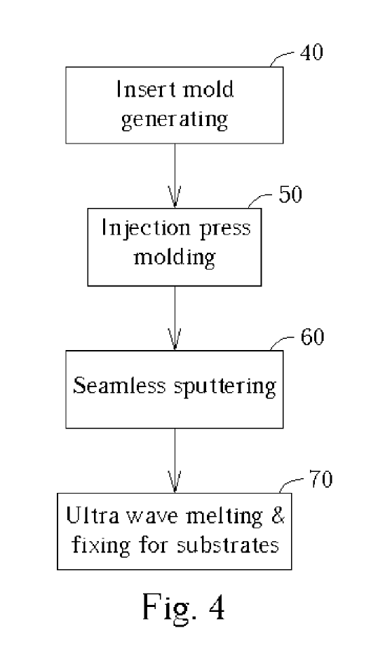

Please refer to FIG. 4. Illustrated in FIG. 4 is a flowchart according to a second preferred embodiment of the present invention. As shown in FIG. 4, at least four processes are necessary to fabricate a multi-layer biochip:

(1) Step 40: Providing an insert mold;

(2) Step 50: Injecting press molding a polymer into the insert mold;

(3) Step 60: Seamless sputtering metal onto the polymer substrate to generate microelectrode sensors; and

(4) Step 70: Ultra wave melting and fixing.

Providing an insert mold: Use photoresist composites to define patterns such as a channel, a depression, or a hole on a substrate. Because the fabricated biochip is multi-layer structure, a plurality of molds may be required in this step.

Injection press molding into the insert mold: Use each above-mentioned insert mold applied with a CD/DVD injector to inject a disk being a flat rectangular plate having a length and a width between 1 cm and 10 cm, depending on a practical design. Patterns of the disk are the same as the mold, such as a channel for flowing testing samples or a space for storing reagents. According to the second preferred embodiment of the present invention, the substrate comprises of polymer plastic material.

Seamless sputtering: As a width of a wire of a pattern on a metal mask could be in the order of μm, to precisely transfer the patterns of the metal mask onto specific area of the polymer substrate, the metal mask must be fixed tightly with the polymer substrate. In the present invention, an object having magnetic force such as a magnet, a permalloy, or an electromagnet is provided behind the polymer substrate to attract the metal mask tightly for sputtering an Au metal electrode pattern on the polymer substrate.

Ultra wave melting and fixing: Fixing each plastic substrate by ultra wave melting and fixing to complete the fabrication processes.

Compared to a prior art, the present invention is compatible with standard CD/DVD making processes. The method includes substrate injection press molding, followed by seamless magnetic biosensor sputtering. If necessary, the sputtered biosensor is cut off from the substrate. Combined with standard CD/DVD making processes and modified seamless sputtering techniques, mass production of plastic biochip and electrochemical biosensor test strip with advantages of low cost and high yield can be achieved.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method compatible to a standard optical disk generation process for manufacturing a electrochemical sensing test strip, the method comprising:
injection press molding a polymer substrate; and
seamless sputtering metal onto the polymer substrate generating microelectrode sensors;
wherein the seamless sputtering includes applying a metal mask having an electrode pattern to a first surface of the polymer substrate and a magnetic material to a second surface of the polymer substrate.

2. The method of claim 1 further comprising removing a chip from the polymer substrate with a stamper having a die with a 33 mm diameter central hole.

3. The method of claim 1 wherein thickness of the polymer substrate is between 0.6 mm and 2.0 mm.

4. The method of claim 1 further comprising performing a cut off process after the seamless sputtering.

5. A method compatible to a standard optical disk generation process for manufacturing a biochip, the method comprising:
providing an insert mold having a pattern;
injection press molding a polymer into the insert mold generating a polymer chip having the pattern of the insert mold; and
seamless sputtering metal onto the polymer chip disposing micro sensing electrodes thereon;
wherein the seamless sputtering includes applying a metal mask having an electrode pattern to a first surface of the polymer chip and a magnetic material to a second surface of the polymer chip.

6. The method of claim 5 wherein the pattern is a channel, a depression, or a hole.

7. The method of claim 5 wherein the chip is a flat rectangular plate having a length and a width between 1 cm and 10 cm.

8. The method of claim 5 further comprising ultra wave melting and fixing the polymer chip after the seamless sputtering.
